(19) United States
(12) Patent Application Publication
(10) Pub. No.: US 2023/0287242 A1
(43) Pub. Date: Sep. 14, 2023

(54) PAD-IN-A-BOTTLE (PIB) TECHNOLOGY FOR COPPER AND THROUGH-SILICON VIA (TSV) CHEMICAL-MECHANICAL PLANARIZATION (CMP)

(71) Applicant: Versum Materials US, LLC, Tempe, AZ (US)

(72) Inventors: XIAOBO SHI, Chandler, AZ (US); MARK O'NEILL, Queen Creek, AZ (US); JOHN LANGAN, Tempe, AZ (US); YASA SAMPURNO, Tucson, AZ (US); ARA PHILIPOSSIAN, Tucson, AZ (US)

(21) Appl. No.: 18/006,240

(22) PCT Filed: Jul. 26, 2021
(86) PCT No.: PCT/US21/43150

§ 371 Date: Jan. 20, 2023

Related U.S. Application Data
(60) Provisional application No. 63/058,289, filed on Jul. 29, 2020.

(51) Int. Cl. C09G 1/02; H01L 21/306

(52) U.S. Cl. CPC C09G 1/02; H01L 21/30625

(57) ABSTRACT

A novel pad-in-a-bottle (PIB) technology for advanced chemical-mechanical planarization (CMP) Copper or THROUGH-SILICON VIA (TSV) CMP compositions, systems and processes has been disclosed. The role of conventional polishing pad asperities is played by high-quality micron-size polyurethane (PU) beads that are comparable to the sizes of pores and asperities in polishing pads.

### CROSS REFERENCE TO RELATED APPLICATION(S)

This application claims the benefit of U.S. Provisional Patent Application No. 63/058,289 filed Jul. 29, 2020, which is incorporated herein by reference as if fully set forth.

### BACKGROUND OF THE INVENTION

This invention relates generally to a novel pad-in-a-bottle (PIB) technology for advanced chemical-mechanical planarization (CMP) compositions, systems, and processes. Specifically, present invention relates to PIB technology for advanced Copper and TSV CMP compositions, systems, and processes.

In CMP, asperities on a polyurethane (PU) pad are irreversibly deformed due to wafer contact and are also abraded by composition particles. As such, the pad surface must be continuously renewed with a diamond disc to ensure process stability. Because diamond disk has to cut the pad surface to eliminate old asperities and create new ones, they also gradually thin the pad, forcing its replacement (FIG. 1).

Thus, conventional CMP has several weaknesses, such as (a) large amounts of waste is created (due to frequent replacement of pads and conditioners), (b) poorly controlled shapes of pad asperities that cause highly-variable contact area distributions. These result in variations in removal rate (RR), and negatively affect wafer-level topography, among other things.

This invention discloses new novel pad-in-a-bottle (PIB) technology for advanced node Copper and TSV CMP compositions, systems and processes developed to meet challenging requirements.

### BRIEF SUMMARY OF THE INVENTION

The needs are satisfied by using the disclosed compositions, methods, and planarization systems for CMP of Copper and TSV substrates.

In one aspect, CMP polishing compositions is provided. The CMP polishing composition comprises:
abrasive,
micron-size polyurethane (PU) beads having a size ranging from 2 to 100 μm, 10 to 80 μm, 20 to 70 μm, or 30 to 50 μm;
silicone-containing dispersing agent;
liquid carrier such as water;
and optionally,
a chelating agent,
corrosion inhibitor,
organic quaternary ammonium salt,
a biocide;
a pH adjusting agent;
an oxidizer added at the point of use; and
the pH of the composition is from 3.0 to 12.0; 4.0 to 11.0; 5.0 to 10.0; 5.5 to 9.0; 6.0 to 8.0; or 6.0 to 7.5.

In another aspect, CMP polishing method is provided. The CMP polishing method comprises:
providing the semiconductor substrate having a surface containing copper or THROUGH-SILICON VIA (TSV) copper;
providing a polishing pad;
providing the chemical mechanical polishing (CMP) formulation stated above;
contacting the surface of the semiconductor substrate with the polishing pad and the chemical mechanical polishing formulation; and
polishing the surface of the semiconductor;
wherein at least a portion of the surface containing Cu film is in contact with both polishing pad and the chemical mechanical polishing formulation.

In yet another aspect, CMP polishing system is provided. The CMP polishing system comprises:
a semiconductor substrate having a surface containing copper or THROUGH-SILICON VIA (TSV) copper;
providing a polishing pad;
providing the chemical mechanical polishing (CMP) formulation in claim stated above;
wherein at least a portion of the surface containing Cu film is in contact with both the polishing pad and the chemical mechanical polishing formulation.

The abrasive are particles include, but are not limited to, colloidal silica or high purity colloidal silica; the colloidal silica particles doped by other metal oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasive particles, surface-coated or modified abrasive particles, or other composite particles, and mixtures thereof.

The silicone-containing dispersing agent includes, but is not limited to, silicone polyethers containing both a water-insoluble silicone backbone and a number of water-soluble polyether pendant groups to provide surface wetting properties. Examples are silicone polyethers containing both a water-insoluble silicone backbone and pendant groups comprising n repeating unit of ethylene oxide (EO) and propylene oxide (PO) (EO-PO) functional groups wherein n is 2 o 25.

The corrosion inhibitors include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The chelating agents (or chelators) include, but are not limited to, amino acid and its derivatives, and organic amine.

The amino acid and its derivatives include, but not limited to, glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The biocide includes but is not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof.

The organic quaternary ammonium salt as Cu removal rate boosting agent and defect reducing agent, includes, but is not limited to, choline salts with different counter ions, such as choline bicarbonate, choline hydroxide, choline dihydrogencitrate salt, choline ethanolamine, choline bitartrate, etc.

The pH adjusting agents include, but are not limited to, the following: nitric acid, hydrochloric acid, sulfuric acid, phosphoric acid, other inorganic or organic acids, and mixtures thereof to adjust pH towards acidic direction. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

### BRIEF DESCRIPTION OF SEVERAL VIEWS OF THE DRAWINGS

FIG. 1 (Prior art) shows a conventional CMP polishing with a polyurethane pad 146.

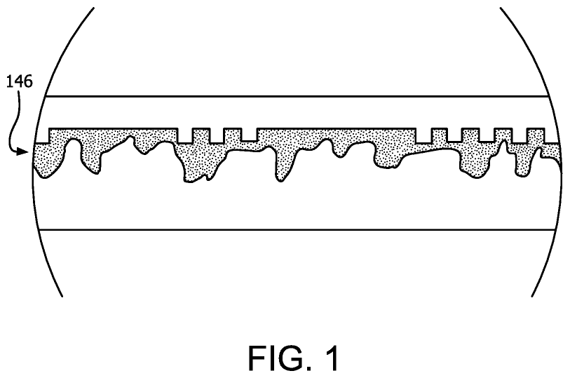

FIG. 2 shows PIB CMP polishing with a polyurethane pad 146 and polyurethane beads (130).

FIG. 3 Cu Removal Rate (Cu RR) using CMP compositions with (Comp. 1) or without polyurethane beads (Ref. and Ref. 1)

FIG. 4 Cu Dishing at 1.5 psi DF and 0.6 m/s Sliding Velocity using CMP compositions with (Comp. 1) or without polyurethane beads (Ref. and Ref. 1)

FIG. 5 Cu Dishing at 1.5 psi DF and 1.0 m/s Sliding Velocity using CM compositions with (Comp. 1) or without polyurethane beads (Ref. and Ref. 1)

FIG. 6 Sliding Velocity on Cu Line Dishing using CMP composition Ref.

FIG. 7 Sliding Velocity on Cu Line Dishing using CMP composition Ref. 1

FIG. 8 Sliding Velocity on Cu Line Dishing using PIB CMP composition Comp. 1

### DETAILED DESCRIPTION OF THE INVENTION

The current application discloses a new technology where the role of pad asperities is played by high-quality micron-size polyurethane (PU) beads having a size ranging from 2 to 100 μm, 10 to 80 μm, 20 to 70 μm, or 30 to 50 μm; that are comparable to the sizes of pores and asperities in commercial polishing pads.

The beads are suspended in a Cu CMP polishing composition having abrasive particles, such as a calcined ceria, colloidal silica, or composite particles with the assistance of a wetting agent (or a surfactant) as the dispersing agent to disperse polyurethane beads in aqueous compositions.

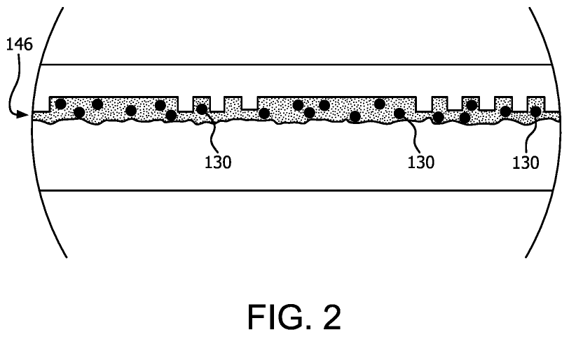

FIG. 2 shows PIB CMP polishing with a polyurethane pad 146 and polyurethane beads (130). The beads come into contact with the wafer surface by a means described below to promote polishing in much the same way as conventional asperities.

By selecting both the size of the beads, and their concentration in the composition, much better control of the height, curvature, and area density of the “summits” that come in contact with the wafer are achieved, substantially reducing the process variability associated with conventional asperity contact.

Use of beads still requires a second surface, or counter-face, for polishing to occur, which in our case continues to be a conventional polyurethane-based pad, but one that requires minimal conditioning as it is no longer the primary surface where polishing takes place. Alternatively, one can use an inexpensive and partially conditioned pad as the counter-face in FIG. 2.

A polisher may use 2 to 3 pads and conditioners simultaneously. End-of-life for a pad and a conditioning disc is typically reached after only 2 days of continuous use. Each platen in a CMP tool, therefore, uses hundreds of pads and conditioners annually, and since wafer fabrication facilities can have dozens of tools (with 2 or 3 platens on each tool), the total cost for pads and pad conditioners alone is substantial.

Since it can take several hours to remove a used pad, install, and qualify a new one, the engineering and product loss due to tool downtime and consumables used to qualify the new pad are also significant. Used PU pads and discarded diamond disc conditioners represent waste from the CMP processes which causes some environmental health and safety (EHS) issues.

As for a polishing pad, only about two-thirds of a pad thickness is used before the pad has to be stripped and discarded. For conditioner, only a few hundred diamonds out of tens of thousands control the product lifetime, after which the conditioner must be discarded. Furthermore, recycle or reuse options are not available for pads and conditioners. Our work addresses the above EHS issues and offers a novel solution to the current standard CMP processes by eliminating the use of lots of pads and diamond disc conditioners.

Polyurethane beads used in the disclosed polishing compositions have a size ranging from 2 to 100 μm, 10 to 80 μm, 20 to 70 μm, or 30 to 50 μm.

Several specific aspects of the present invention are outlined below.

In one aspect, CMP polishing compositions is provided.

Aspect 1: A CMP polishing composition comprising:
an abrasive,
micron-size polyurethane (PU) beads;
silicone-containing dispersing agent;
liquid carrier such as water;
and optionally
a chelating agent;
corrosion inhibitor;
organic quaternary ammonium salt;
a biocide;
a pH adjusting agent;
an oxidizer added at the point of use; and
the pH of the composition is from 3.0 to 12.0; 4.0 to 11.0; 5.0 to 10.0; 5.5 to 9.0; 6.0 to 8.0; or 6.0 to 7.5.
   Aspect 2: A CMP polishing method comprising:
providing the semiconductor substrate having a surface containing Copper or TSV Copper;
providing a polishing pad;
providing the chemical mechanical polishing (CMP) formulation stated above;
contacting the surface of the semiconductor substrate with the polishing pad and the chemical mechanical polishing formulation; and
polishing the surface of the semiconductor;
wherein at least a portion of the surface containing Cu film is in contact with both polishing pad and the chemical mechanical polishing formulation.
   Aspect 3: A CMP polishing system comprises:
a semiconductor substrate having a surface containing Cu film;
providing a polishing pad;
providing the chemical mechanical polishing (CMP) formulation in claim stated above;
wherein at least a portion of the surface containing Cu film is in contact with both the polishing pad and the chemical mechanical polishing formulation.

The abrasive are nano-sized abrasive particles, include, but are not limited to, colloidal silica or high purity colloidal silica; the colloidal silica particles doped by other metal oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasive particles, surface-coated or modified abrasive particles, or other composite particles, and mixtures thereof.

The colloidal silica can be made from silicate salts, the high purity colloidal silica can be made from TEOS or TMOS. The colloidal silica or high purity colloidal silica can have narrow or broad particle size distributions with mono-model or multi-models, various sizes and various shapes including spherical shape, cocoon shape, aggregate shape and other shapes.

The nano-sized particles also can have different shapes, such as spherical, cocoon, aggregate, and others.

The particle size of the abrasive particles used in the Cu CMP slurries is ranged from 5 nm to 500 nm, 10 nm to 250 nm, or 25 nm to 100 nm.

The Cu CMP polishing compositions comprise 0.0025 wt. % to 25 wt. %; 0.0025 wt. % to 2.5 wt. %; 0.005 wt. % to 0.5 wt. %; or 0.005 wt. % to 0.15 wt. % of abrasive particles.

The CMP polishing compositions comprise silicone-containing dispersing agent to disperse the polyurethane beads in aqueous solutions. The silicone-containing dispersing agent also functions as a surface wetting agent dispersing agent.

The silicone-containing dispersing agent includes, but is not limited to, silicone polyethers containing both a water-insoluble silicone backbone and a number of water-soluble polyether pendant groups to provide surface wetting properties. Examples are silicone polyethers containing both a water-insoluble silicone backbone and pendant groups comprising n repeating unit of ethylene oxide (EO) and propylene oxide (PO) (EO-PO) functional groups wherein n is 2 o 25.

Examples of the silicone-containing dispersing agent includes Silsurf® E608, Silsurf® J208-6, Silsurf® A208, Silsurf® CR1115, Silsurf® A204, Silsurf® A004-UP, Silsurf® A008-UP, Silsurf® B608, Silsurf® C208, Silsurf® C410, Silsurf® D208, Silsurf® D208, Silsurf® D208-30, Silsurf® Di-1010, Silsurf® Di-1510, Silsurf® Di-15-I, Silsurf® Di-2012, Silsurf® Di-5018-F, Silsurf® G8-I, Silsurf® J1015-O, Silsurf® J1015-O-AC, Silsurf® J208, Silsurf® J208-6, Siltech® OP-8, Siltech® OP-11, Siltech® OP-12, Siltech® OP-15, Siltech® OP-20; the products from Siltech Corporation; 225 Wicksteed Avenue, Toronto Ontario, Canada M4H 1G5.

The concentration range of the silicone-containing dispersing agent is from 0.01 wt. % to 2.0 wt. %, 0.025 wt. % to 1.0 wt. %, or 0.05 wt. % to 0.5 wt. %.

The CMP slurry contains various sized polyurethane beads.

Polyurethane beads used in the disclosed polishing compositions have a size ranging from 2 to 100 μm, 10 to 80 μm, 20 to 70 μm, or 30 to 50 μm;

The concentration range of the polyurethane beads is from 0.01 wt. % to 2.0 wt. %, 0.025 wt. % to 1.0 wt. %, or 0.05 wt. % to 0.5 wt. %.

Polyurethane beads are different from the disclosed abrasive particles. They are not considered as abrasive particles in this disclosure.

The organic quaternary ammonium salt as Cu removal rate boosting agent and defect reducing agent, includes but is not limited to choline salt, such as choline bicarbonate salt, or all other salts formed between choline and other anionic counter ions.

In one embodiment, the CMP slurry contains 0.005 wt. % to 0.25 wt. %, 0.001 wt. % to 0.05 wt. %; or 0.002 wt. % to 0.01 wt. % of quaternary ammonium salt.

In another embodiment, The CMP slurry contains 0.005 wt. % to 0.5 wt. %, 0.001 wt. % to 0.25 wt. %; or 0.002 wt. % to 0.1 wt. % of quaternary ammonium salt.

The chelating agents (or chelators) include, but are not limited to, amino acid, its derivatives, and organic amine.

The amino acid and its derivatives include, but not limited to, glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The CMP slurry contains 0.1 wt. % to 18 wt. %; 0.5 wt. % to 15 wt. %; 1.0 wt. % to 10.0 wt. %; or 2.0 wt. % to 10.0 wt. % of the chelating agent.

The corrosion inhibitors can be any known reported corrosion inhibitors.

The corrosion inhibitors for example, include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The CMP slurry contains 0.005 wt. % to 1.0 wt. %; 0.01 wt. % to 0.5 wt. %; or 0.025 wt. % to 0.25 wt. % of corrosion inhibitor.

A biocide having active ingredients for providing more stable shelf time of the Cu chemical mechanical polishing compositions can be used.

The biocide includes but is not limited to Kathon™, Kathon™ CG/ICP II, from Dow Chemical Co. They have active ingredients of 5-chloro-2-methyl-4-isothiazolin-3-one and/or 2-methyl-4-isothiazolin-3-one.

The CMP slurry contains 0.0001 wt. % to 0.05 wt. %; 0.0001 wt. % to 0.025 wt. %; or 0.0001 wt. % to 0.01 wt. % of biocide.

Acidic or basic compounds or pH adjusting agents can be used to allow pH of CMP polishing compositions being adjusted to the optimized pH value,

The pH adjusting agents include, but are not limited to, the following: nitric acid, hydrochloric acid, sulfuric acid, phosphoric acid, other inorganic or organic acids, and mixtures thereof to adjust pH towards acidic direction. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

The CMP slurry contains 0 wt. % to 1 wt. %; 0.01 wt. % to 0.5 wt. %; or 0.1 wt. % to 0.25 wt. % of pH adjusting agent.

pH of the Cu polishing compositions is from about 3.0 to about 12.0; about 4.0 to about 11.0; about 5.0 to about 10.0; about 5.5 to about 9.0 about 6.0 to about 8.0; or about 6.0 to about 7.5.

Various per-oxy inorganic or organic oxidizing agents or other types of oxidizing agents can be used to oxidize the metallic copper film to the mixture of copper oxides to allow their quick reactions with chelating agents and corrosion inhibitors.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof. The preferred oxidizer is hydrogen peroxide.

The CMP composition contains 0.1 wt. % to 10 wt. %; 0.25 wt. % to 3 wt. %; or 0.5 wt. % to 2.0 wt. % of oxidizing agents.

### Experimental Section

### Parameters

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min
Removal Rates (RR):
Cu RR 1.5 psi Measured Copper removal rate at 1.5 psi down pressure of the CMP tool
Cu RR 2.0 psi Measured Copper removal rate at 2.0 psi down pressure of the CMP tool
Cu RR 3.0 psi Measured Copper removal rate at 3.0 psi down pressure of the CMP tool

### General Experimental Procedure

All percentages in the compositions are weight percentages unless otherwise indicated.

In the examples presented below, CMP experiments were run using the procedures and experimental conditions given below. The CMP tool that was used in the examples is a 200 mm Mirra® polisher, manufactured by Applied Materials, 3050 Boweres Avenue, Santa Clara, Calif., 95054. An IC1000 pad or other type of polishing pad, supplied by DuPont Company was used on the platen for the blanket wafer polishing studies. Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by Planarization Platform of Versum Materials, Inc. at baseline conditions. Polishing experiments were conducted using blanket Cu wafers with and Cu MIT854 200 mm patterned wafers. These blanket wafers were purchased from Silicon Valley Microelectronics, 1150 Campbell Ave, CA, 95126.

Polishing pad, IC1000 pad or Other polishing pad was used during Cu CMP, supplied by DuPont Company

### Working Example

The reference (Ref.) CMP composition comprised of 3.78 wt. % glycine, 0.1892 wt. % Amitrole, 0.004 wt. % ethylenediamine, 0.00963 wt. % choline bicarbonate, 0.0001 wt. % Kathon II biocide, and 0.0376 wt. % high purity colloidal silica particles abrasive.

Silsurf E608 containing EO-PO wetting functional groups was used as the silicone-containing dispersing agent.

The second CMP composition (Ref. 1) was prepared by adding 0.05 wt. % Silsurf E608 to the Reference Cu CMP composition (Ref.). The second CMP composition was used to inspect the effects of the dispersing agent on CMP polishing performances vs the reference CMP composition.

The third CMP composition (Comp. 1), PIB working CMP composition was prepared by adding 0.05 wt. % Silsurf E608 and 0.10 wt. % 35 mm sized polyurethane beads (PU beads) into the reference Cu CMP composition (Ref.).

2.0 wt. % H₂O₂ was added into the CMP compositions at the point of use.

All three compositions had a pH around 7.15.

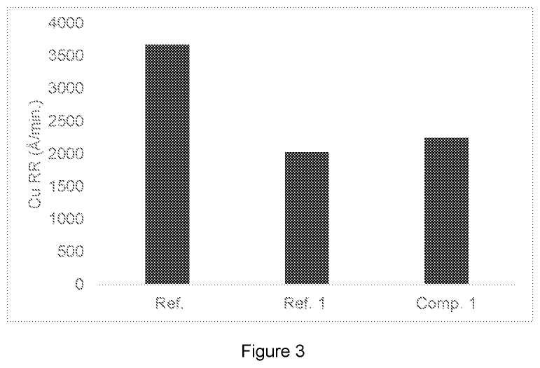

The Cu removal rates were tested using those three Cu CMP compositions, and the results were listed in Table 1 and depicted in FIG. 3.

TABLE 1
Cu Removal Rate Comparison in Cu Compositions

| Compositions | Ave. Cu RR (Å/min.) |
|---|---|
| Ref. | 3672 |
| Ref. 1 | 2025 |
| Comp. 1 | 2247 |

As the results shown in Table 1 and FIG. 3, the Cu removal rates were reduced for the second and the third CMP compositions comparing with the reference Cu composition (Ref.) due to the passivation effects of the dispersing agent on copper oxide surface in CMP polishing process.

The results also shown that the Cu removal rates were increased by about 11% from the PIB working CMP composition (Comp. 1) than the Cu removal rates obtained from the second CMP composition (Ref. 1).

The results have shown one of the benefits of using micron sized PU beads in Cu CMP compositions, the Cu removal rates can be increased.

The same three CMP composition were used to polish Cu patterned wafers.

In polishing Cu patterned wafers, 1.5 psi down force was applicated at two different sliding velocity speeds, 0.6 m/s or 1.0 m/s respectively.

TABLE 2
Cu Dishing Comparison at 1.5 psi DF and 0.6 m/s Sliding Velocity

| Compositions | 100 × 100 μm | 50 × 50 μm | 9 × 1 μm | 10 × 10 μm | 1 × 1 μm | 1 × 9 μm |
|---|---|---|---|---|---|---|
| Ref. | 2730 | 1994 | 1080 | 1043 | 626 | 530 |
| Ref. 1 | 2313 | 1858 | 1592 | 1328 | 1076 | 969 |
| Comp. 1 | 1588 | 1197 | 1019 | 784 | 661 | 550 |

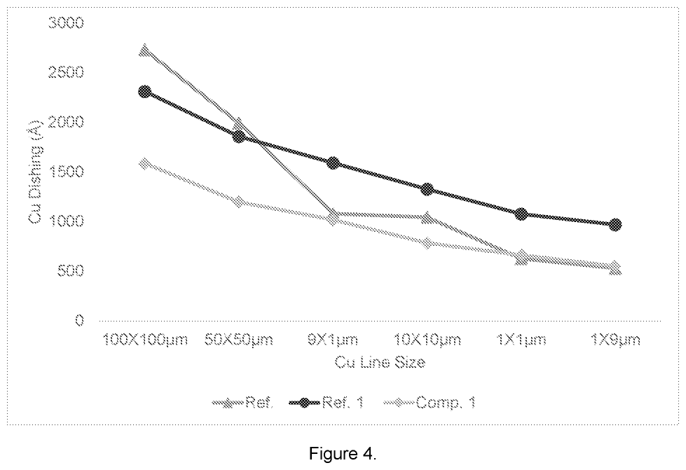

The Cu line dishing obtained from the compositions at 1.5 psi DF and with 0.6 m/s sliding velocity results were listed in Table 2 and depicted in FIG. 4.

For the composition with the addition of 0.05 wt. % dispersing agent only (Ref. 1), the Cu dishing were reduced on 100×100 μm and 50×50 μm line features, but no reduction on the rest four Cu line features.

For the composition with the addition of 0.05 wt. % dispersing agent and 0.1 wt. % 35 mm PU beads (Comp. 1); Cu line dishing was significantly reduced across all six tested Cu line features comparing with the other two compositions.

The effective Cu line dishing reductions was derived from PIB working CMP composition that used PU beads.

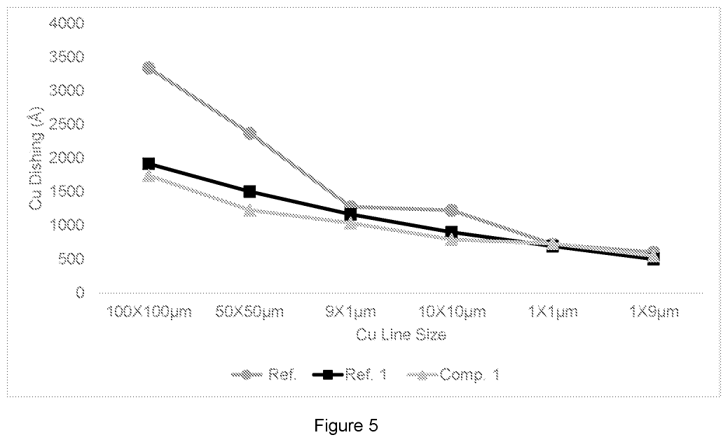

The Cu line dishing obtained from the compositions at 1.5 psi DF and with 1.0 m/s sliding velocity results were listed in Table 3 and depicted in FIG. 5.

TABLE 3
Cu Dishing Comparison at 1.5 psi DF and 1.0 m/s Sliding Velocity

| Compositions | 100 × 100 μm | 50 × 50 μm | 9 × 1 μm | 10 × 10 μm | 1 × 1 μm | 1 × 9 μm |
|---|---|---|---|---|---|---|
| Ref. | 3340 | 2369 | 1276 | 1226 | 721 | 601 |
| Ref. 1 | 1916 | 1504 | 1165 | 899 | 692 | 500 |
| Comp. 1 | 1742 | 1229 | 1036 | 792 | 732 | 548 |

For the composition with the addition of 0.05 wt. % dispersing agent only (Ref. 1), Cu line dishing was reduced across all six tested Cu line features.

For the composition with the addition of 0.05 wt. % dispersing agent and 0.1 wt. % 35 mm PU beads (Comp. 1), Cu line dishing was significantly reduced across tested Cu line features except for 1×1 μm.

TABLE 4
Sliding Velocity on Cu Line Dishing using Cu Reference composition (Ref.)

| Ref. at Sliding | | | | | | |
|---|---|---|---|---|---|---|
| Velocity (m/s) | 100 × 100 μm | 50 × 50 μm | 9 × 1 μm | 10 × 10 μm | 1 × 1 μm | 1 × 9 μm |
| 0.6 m/s | 2730 | 1994 | 1080 | 1043 | 626 | 530 |
| 1.0 m/s | 3340 | 2369 | 1276 | 1226 | 721 | 601 |

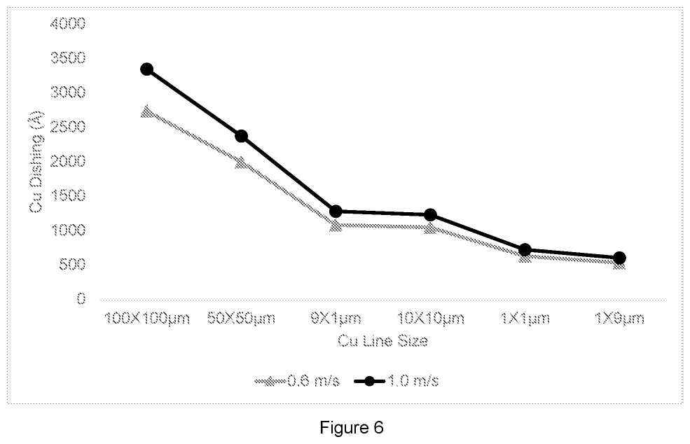

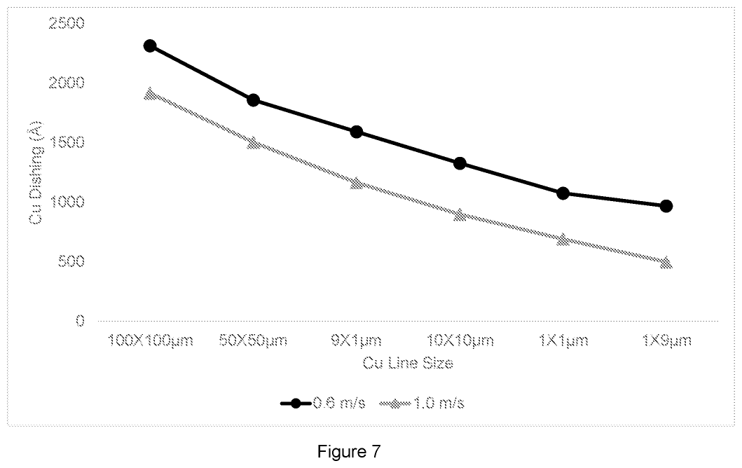

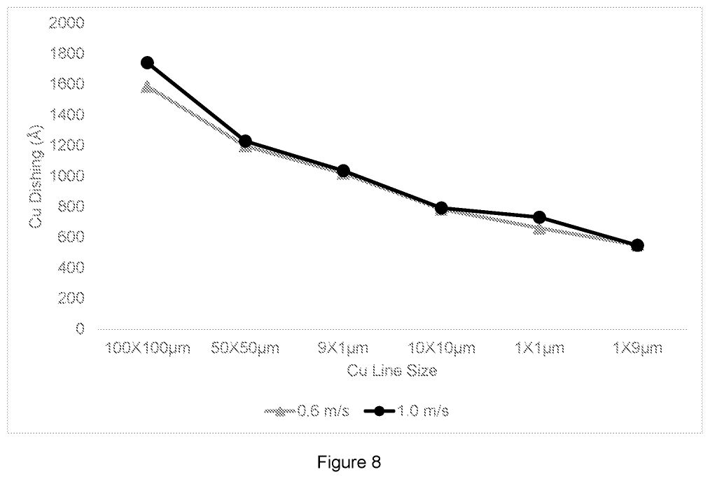

The effects of sliding velocity of 0.6 m/s vs 1.0 m/s at same applied down force 1.5 psi on Cu line dishing across all six tested Cu line features were examined and the results were listed in Table 4, Table 5, Table 6 and FIG. 6, FIG. 7 and FIG. 8, respectively.

As the results shown in Table 4 and FIG. 6, Cu line dishing across all six tested Cu line features were all increased and changed significantly as sliding velocity increased from 0.6 m/s to 1.0 m/s.

TABLE 5
Effects of Sliding Velocity on Cu Dishing in Cu + Dispersing Agent (Ref. 1)

| Ref. 1 at Sliding | | | | | | |
|---|---|---|---|---|---|---|
| Velocity (m/s) | 100 × 100 μm | 50 × 50 μm | 9 × 1 μm | 10 × 10 μm | 1 × 1 μm | 1 × 9 μm |
| 0.6 m/s | 2313 | 1858 | 1592 | 1328 | 1076 | 969 |
| 1.0 m/s | 1916 | 1504 | 1165 | 899 | 692 | 500 |

As the results shown in Table 5 and FIG. 7, Cu line dishing across all six tested Cu line features were all reduced and changed significantly as sliding velocity increased from 0.6 m/s to 1.0 m/s.

As the results shown in Table 6 and FIG. 8, Cu line dishing across all six tested Cu line features have very slightly changes for PIB working CMP composition containing 35 mm PU beads as sliding velocity increased from 0.6 m/s to 1.0 m/s.

TABLE 6
Effects of Sliding Velocity on Cu Dishing using PIB CMP composition(Comp. 1)

| Comp. 1 at | | | | | | |
|---|---|---|---|---|---|---|
| Sliding Velocity | | | | | | |
| (m/s) | 100 × 100 μm | 50 × 50 μm | 9 × 1 μm | 10 × 10 μm | 1 × 1 μm | 1 × 9 μm |
| 0.6 m/s | 1588 | 1197 | 1019 | 784 | 661 | 550 |
| 1.0 m/s | 1742 | 1229 | 1036 | 792 | 732 | 548 |

Clearly, PIB working CMP composition containing PU beads over performs the Cu polishing compositions without using PU beads in providing more stable over polishing windows vs sliding velocity changes.

The Cu removal rates, and Cu line dishing were obtained at 1.5 psi down force and 0.6 m/s sliding velocity using three compositions were compared and the results were listed in Table 7.

TABLE 7
Cu RR & Cu Dishing Comparison at 1.5 psi and 0.6 m/s Sliding Velocity

| | | | | | | | Ave. Cu |
|---|---|---|---|---|---|---|---|
| | | | | | | | RR |
| Compositions | 100 × 100 μm | 50 × 50 μm | 9 × 1 μm | 10 × 10 μm | 1 × 1 μm | 1 × 9 μm | (Å/min.) |
| Ref. | 2313 | 1858 | 1592 | 1328 | 1076 | 969 | 2025 |
| Ref. 1 | 1588 | 1197 | 1019 | 784 | 661 | 550 | 2247 |
| Comp.1 | −31.3% | −35.6% | −36.0% | −41.0% | −38.6% | −43.3% | +11.1% |

As the results shown in Table 7, comparing with the Cu polishing compositions without the use of PIB, the PIB working CMP composition containing PU beads not only increased Cu removal rate by 11%, but also significantly reduced Cu line dishing across all six tested Cu line features in the range of 31% to 43%.

The PIB technology has also shown to reduce the lateral vibration of the wafer during polishing significantly.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical mechanical polishing (CMP) composition comprising:
an abrasive;
polyurethane (PU) beads;
a silicone-containing dispersing agent;
water;
a chelating agent selected from the group consisting of amino acid and its derivatives, organic amine, and combinations thereof;
and
optionally at least one selected from the group consisting of
a corrosion inhibitor;
an organic quaternary ammonium salt;
a biocide;
a pH adjusting agent; and
an oxidizer;
wherein the pH of the composition is from 3.0 to 12.0.

2. The CMP composition of claim 1, wherein the abrasive are abrasive particles selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; inorganic metal oxide particles selected from the group consisting of alumina, titania, zirconia, and ceria; diamond particles; silicon nitride particles; mono-modal, bi-modal, or multi-modal colloidal abrasive particles; organic polymer-based soft abrasive particles; surface-coated or modified abrasive particles; and combinations thereof; and the abrasive ranges from 0.005 wt. % to 0.5 wt. %.

3. The CMP composition of claim 1, wherein the polyurethane (PU) beads have a size from 10 to 80 μm; and the polyurethane (PU) beads range from 0.025 wt. % to 1.0 wt. %.

4. The CMP composition of claim 1, wherein the silicone-containing dispersing agent comprises a silicone polyether containing both a water-insoluble silicone backbone and water-soluble polyether pendant groups, and the silicone-containing dispersing agent ranges from 0.025 wt. % to 1.0 wt. %.

5. The CMP composition of claim 1, wherein the silicone-containing dispersing agent comprises a silicone polyether containing both a water-insoluble silicone backbone and pendant groups comprising n repeating unit of ethylene oxide (EO) and propylene oxide (PO) (EO-PO) functional groups, wherein n is 2 o 25; and the silicone-containing dispersing agent ranges from 0.025 wt. % to 1.0 wt. %.

6. The CMP composition of claim 1, wherein the CMP composition comprises the chelating agent selected from the group consisting of glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and the chelating agent ranges from 0.5 wt. % to 15 wt. %.

7. The CMP composition of claim 1, wherein the CMP composition further comprises the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof; and the corrosion inhibitor ranges from 0.005 wt. % to 1.0 wt. %.

8. The CMP composition of claim 1, wherein the CMP composition comprises
the abrasive selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; inorganic metal oxide particles selected from the group consisting of alumina, titania, zirconia, and ceria; diamond particles; silicon nitride particles; mono-modal, bi-modal, or multi-modal colloidal abrasive particles; organic polymer-based soft abrasive particles; surface-coated or modified abrasive particles; and combinations thereof;
the polyurethane (PU) beads have a size from 10 to 80 μm, 20 to 70 μm;
the silicone-containing dispersing agent comprises a silicone polyether containing both a water-insoluble silicone backbone and pendant groups comprising n repeating unit of ethylene oxide (EO) and propylene oxide (PO) (EO-PO) functional groups wherein n is 2 o 25;
the chelating agents selected from the group consisting of the group consisting of glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and
the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof.

9. The CMP composition of claim 1, wherein the CMP composition further comprises the biocide having an active ingredient selected from the group consisting of 5-chloro-2-methyl-4-isothiazolin-3-one, 2-methyl-4-isothiazolin-3-one, and combinations thereof; and the biocide ranges from 0.0001 wt. % to 0.05 wt. %.

10. The CMP composition of claim 1, wherein the CMP composition comprises the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and the oxidizing agent ranges from 0.1 wt. % to 10 wt. %.

11. The CMP composition of claim 1, wherein the CMP composition comprises
the abrasive selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; inorganic metal oxide particles selected from the group consisting of alumina, titania, zirconia, and ceria; diamond particles; silicon nitride particles; mono-modal, bi-modal, or multi-modal colloidal abrasive particles; organic polymer-based soft abrasive particles; surface-coated or modified abrasive particles; and combinations thereof;
the polyurethane (PU) beads have a size from 10 to 80 μm;
the silicone-containing dispersing agent comprises a silicone polyether containing both a water-insoluble silicone backbone and pendant groups comprising n repeating unit of ethylene oxide (EO) and propylene oxide (PO) (EO-PO) functional groups wherein n is 2 o 25;
the chelating agents selected from the group consisting of the group consisting of glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof.

12. The CMP composition of claim 1, wherein the CMP composition comprises the organic quaternary ammonium salt selected from the group consisting of choline salt having different counter ions selected from the group consisting of choline bicarbonate, choline hydroxide, choline dihydrogencitrate salt, choline ethanolamine, choline bitartrate, and combinations thereof; and the organic quaternary ammonium salt ranges from 0.005 wt. % to 0.25 wt. %.

13. The CMP composition of claim 1, wherein the CMP composition comprises
the abrasive selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; inorganic metal oxide particles selected from the group consisting of alumina, titania, zirconia, and ceria; diamond particles; silicon nitride particles; mono-modal, bi-modal, or multi-modal colloidal abrasive particles; organic polymer-based soft abrasive particles; surface-coated or modified abrasive particles; and combinations thereof;
the polyurethane (PU) beads have a size from 10 to 80 μm;
the silicone-containing dispersing agent comprises a silicone polyether containing both a water-insoluble silicone backbone and pendant groups comprising n repeating unit of ethylene oxide (EO) and propylene oxide (PO) (EO-PO) functional groups wherein n is 2 o 25;
the chelating agents selected from the group consisting of the group consisting of glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof;
the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the organic quaternary ammonium salt selected from the group consisting of choline salt having different counter ions selected from the group consisting of choline bicarbonate, choline hydroxide, choline dihydrogencitrate salt, choline ethanolamine, choline bitartrate, and combinations thereof.

14. The CMP composition of claim 1, wherein the CMP composition comprises the pH adjusting agent selected from the group consisting of nitric acid, hydrochloric acid, sulfuric acid, phosphoric acid, other inorganic or organic acids, and combinations thereof to adjust pH towards acidic direction; or is selected from the group consisting of sodium hydride, potassium hydroxide, ammonium hydroxide, tetraalkyl ammonium hydroxide, organic amines, and combinations thereof to adjust pH towards alkaline direction; and the CMP composition has a pH of about 5.5 to about 9.0.

15. (canceled)

16. (canceled)

17. The CMP composition of claim 1, wherein the CMP composition comprises colloidal silica particles; silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 o 25; polyurethane (PU) beads; at least two chelating agent selected from the group consisting of the group consisting of glycine, D-alanine, L-alanine, DL-alanine, beta-alanine, valine, leucine, isolueciene, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof; and the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof;

18. The CMP composition of claim 1, wherein the CMP composition comprises glycine, amitrole, ethylenediamine, choline bicarbonate, biocide, colloidal silica particles, silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 o 25, and polyurethane (PU) beads.

19. The CMP composition of claim 1, wherein the CMP composition comprises glycine, amitrole, ethylenediamine, choline bicarbonate, biocide, colloidal silica particles, silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 o 25, and polyurethane (PU) beads; wherein the CMP composition comprises has a pH of 5.5 to 9.0.

20. The CMP composition of claim 1, wherein the CMP composition comprises glycine, amitrole, ethylenediamine, choline bicarbonate, biocide, and colloidal silica particles, silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 o 25, and polyurethane (PU) beads; wherein the CMP composition comprises has a pH of 6.0 to 8.0.

21. A method of chemical mechanical polishing a semiconductor substrate, comprising steps of:
providing the semiconductor substrate having a surface containing Copper or THROUGH-SILICON VIA (TSV) Copper;
providing a polishing pad;
providing the chemical mechanical polishing (CMP) composition of claim 1;
contacting the surface of the semiconductor substrate with the polishing pad and the chemical mechanical polishing (CMP) composition; and
polishing the surface containing Copper or TSV Copper.

22. A system of chemical mechanical polishing, comprising
a semiconductor substrate having a surface containing copper or THROUGH-SILICON VIA (TSV) copper;
a polishing pad;
the chemical mechanical polishing (CMP) composition of claim 1;
wherein at least a portion of the surface containing copper or TSV copper is in contact with both the polishing pad and the chemical mechanical polishing formulation.
